(19) United States
(12) Patent Application Publication
(10) Pub. No.: US 2010/0200594 A1
(43) Pub. Date: Aug. 12, 2010

(54) Thermal Radiation Shield, a Cryostat Containing a Cooled Magnet and an MRI System Comprising a Radiation Shield

(75) Inventors: Trevor Bryan Husband, Lower Heyford (GB); Stephen Paul Trowell, Alvingham (GB); Philip Alan Charles Walton, Witney (GB)

Correspondence Address: CROWELL & MORING LLP;INTELLECTUAL PROPERTY GROUP, P.O. BOX 14300, WASHINGTON, DC, 20044-4300, US

(73) Assignee: Siemens Plc., Frimley (GB)

(21) Appl. No.: 12/638,640

(22) Filed: Dec. 15, 2009

(30) Foreign Application Priority Data
Feb. 10, 2009 (GB) 0902148.6

(51) Int. Cl. F17C 13/00; F17C 3/04; G01R 33/44

(52) U.S. Cl. 220/560.13; 62/51.1; 324/318

(57) ABSTRACT

The present invention provides a thermal radiation shield (1) for a cryostat, formed of a plastic-metal hybrid material, which comprises a plastic component (23) and a conductive filler material (21) comprising a metal. The thermal radiation shield may be formed by injection moulding.

This invention relates to a thermal radiation shield for use in a cryostat and in particular to a thermal radiation shield for use in a cryostat housing a cooled superconducting magnet, useful in a Magnetic Resonance Imaging (MRI) system.

An MRI system typically employs a large superconducting magnet which requires cooling to a cryogenic temperature, for example liquid helium temperature, for successful operation. A cryostat is provided to enclose the magnet and to hold a large volume of liquid cryogen, such as helium, to provide the cooling.

Liquid helium, in particular, is very expensive and thus the cryostat is designed to minimise loss of liquid helium through heating from the environment where the MRI system is located. Liquid helium will be used as an example cryogen in the present description, but the present application is not limited to application in helium-cooled arrangements. Indeed, the present invention may be applied to cryostats employing any suitable cryogen.

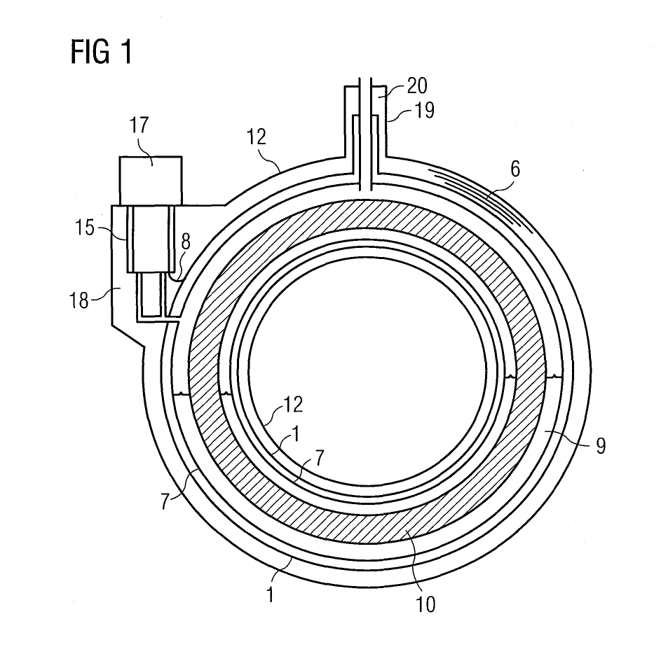

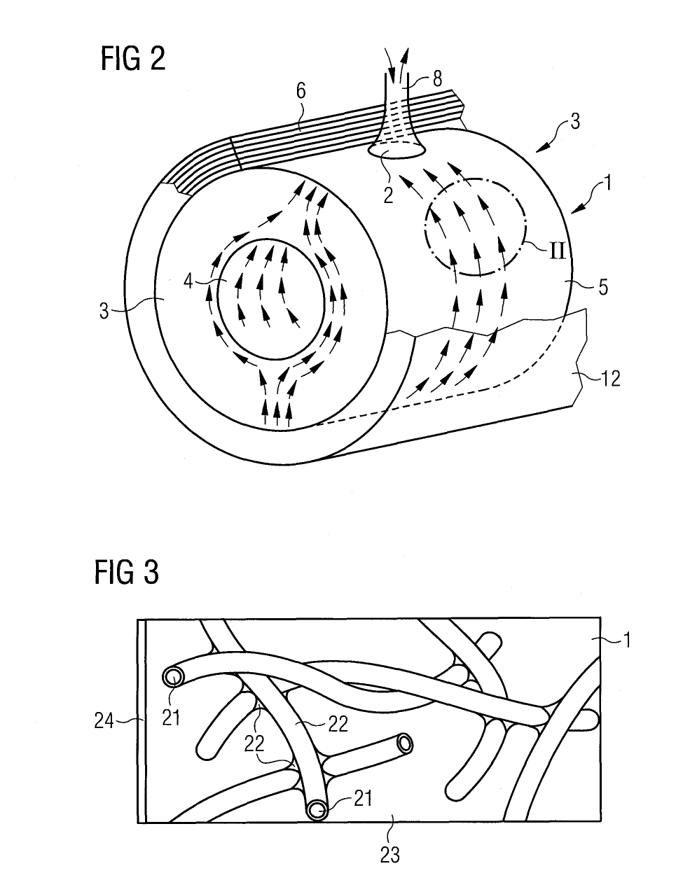

A multilayer structure is provided which is designed to minimise heat reaching the cryogen from the surrounding environment by conduction, convection and radiation, as will be explained in more detail with reference to FIGS. 1 and 2.

FIG. 1 shows a cross-section through a conventional cryostat housing a superconducting magnet. FIG. 2 shows a partial cut-away view of certain components of the cryostat of FIG. 1, particularly illustrating the thermal radiation shield which is the subject of the present invention.

FIG. 1 shows a conventional arrangement of a cryostat including a cryogen vessel 7. A cooled superconducting magnet 10 is provided within cryogen vessel 7, partially immersed within a liquid cryogen 9. The magnet is held in position relative to the cryogen vessel by suspension means (not shown). The cryogen vessel 7 is itself retained within an outer vacuum chamber (OVC) 12 by suspension means (not shown). One or more thermal radiation shields 1 are provided in the vacuum space between the cryogen vessel 7 and the outer vacuum chamber 12. The thermal radiation shield(s) 1 are retained in position relative to the cryogen vessel 7 and the OVC 12 by suspension means (not shown). A number of layers 6 of MYLAR® aluminised polyester film and insulating mesh are typically provided, surrounding the thermal radiation shield between the thermal radiation shield 1 and the OVC 12. These layers are only partially shown in FIG. 1, for clarity. The thermal radiation shield 1 and layers 6 minimise heat transfer from the OVC 12 to the cryogen vessel 7 by radiation. The volume between the OVC 12 and the cryogen vessel 7 is evacuated during manufacture to minimise heat transfer from the OVC to the cryogen vessel by convection.

In some known arrangements, a refrigerator 17 is mounted in a refrigerator sock 15 located in a turret 18 provided for the purpose, towards the side of the cryostat. Alternatively, a refrigerator may be located within access turret 19, which retains access neck (vent tube) 20 mounted at the top of the cryostat. The refrigerator provides active refrigeration to cool cryogen gas within the cryogen vessel 7, in some arrangements by recondensing it into a liquid. The refrigerator 17 may also serve to cool the radiation shield 1. As illustrated in FIG. 1, the refrigerator 17 may be a two-stage refrigerator. A first cooling stage is thermally linked to the radiation shield 16 through thermal link 8, and provides cooling to a first temperature, typically in the region of 80-100K. A second cooling stage provides cooling of the cryogen gas to a much lower temperature, typically in the region of 4-10K.

Electrical connections are provided to the magnet, but are not illustrated for clarity, and as they play no part in the present invention.

In alternative arrangements, large volumes of liquid cryogen are not used, and no cryogen vessel 7 need be present. However, the thermal radiation shield 1 is still provided, and the present invention may be applied to such arrangements.

As is shown in FIG. 2, radiation shield 1 of an MRI system is typically formed as a generally cylindrical annular structure with two annular end faces 3, only one of which is visible, an inner cylinder 4 and an outer cylinder 5.

As described with reference to FIG. 1, the thermal radiation shield 1 typically surrounds a cryogen vessel 7 containing liquid cryogen 9 such as helium to cool a superconducting magnet 10. About the thermal radiation shield 1 is located a number of insulation layers 6 of reflective MYLAR® material (aluminised polyester sheet) and insulating mesh. Outer vacuum container (OVC) 12, also of generally cylindrical configuration, is provided around the thermal radiation shield 1.

A refrigeration unit, such as refrigerator 17 in FIG. 1, is provided in good thermal contact 8 to a cooling area 2 on the thermal radiation thermal radiation shield 1. In operation, this maintains the thermal radiation shield 1 at a temperature of about 52 Kelvin.

Thermal influx due to radiation, and conduction along suspension elements, will cause heating of the thermal radiation shield 1. There will exist a temperature gradient from the cooling area 2 to the remainder of the thermal radiation shield 1. Heat will be conducted in the direction of the arrows shown in FIG. 2, from the remainder of the thermal radiation shield to the cooling area 2, shown at the top of the thermal radiation shield in this example. Heat flows to the cooling area 2 approximately circumferentially on inner and outer cylinders 4, 5, and approximately vertically on the end faces 3.

The thermal radiation shield 1 is conventionally formed of high grade aluminium to provide highly reflective surfaces to minimise radiation of heat into the cryogen vessel 7, and to minimise absorption of heat radiated from the OVC 12. A further advantage of aluminium as the material of the thermal radiation shield is its high thermal conductivity. A problem with such thermal radiation shields is that they have a high electrical conductivity and so permit the generation of eddy currents which oppose magnetic fields produced by in an MRI system in operation, leading to inefficiencies and, in particular, may make the interpretation of the resultant images more difficult particularly if the eddy currents are not evenly distributed.

Reducing the electrical conductivity of the material used for the thermal radiation shield would alleviate the problem of eddy current generation, but materials of lower electrical conductivity tend to also have low thermal conductivity. Sufficient thermal performance must be maintained in order for the thermal radiation shield to perform its function.

The present invention aims to provide a thermal radiation shield of a material which has reduced electrical conductivity as compared to conventional sheet metal thermal radiation shields, yet which has sufficient thermal conductivity for the thermal radiation shield to perform its function.

The conventional thermal radiation shield is formed from sheet metal, and requires skilled assembly and installation. Further skilled operations are required to attach ancillary components to the thermal radiation shield, for example cables, connectors and thermal intercepts such as laminates or copper braids.

The present invention aims to provide a thermal radiation shield which may be constructed and installed using less skilled labour, potentially reducing the cost of production of the complete cryostat, and reducing the time taken to install the thermal radiation shield.

The present invention arose from the realisation that the material of the thermal radiation shield could be tailored to provide the required heat conduction properties whilst minimising the generation of eddy currents by providing reduced electrical conductivity.

According to the invention there is provided a thermal radiation shield, a cryostat and an MRI system as defined in the appended claims.

The above, and further, objects, characteristics and advantages of the present invention will become more apparent from the following description of specific embodiments of the invention, given by way of examples only, with reference to the accompanying drawings in which:

FIG. 1 shows a cross-section through a conventional cryostat housing a superconducting magnet;

FIG. 2 shows a partial cut-away view of certain components of the cryostat of FIG. 1, including a radiation thermal radiation shield in accordance with the invention; and

FIG. 3 shows an enlarged cross-sectional view of part of a thermal radiation shield according to an embodiment of the invention.

Various plastic-metal hybrid materials are known. Typically, these consist of a plastic, either thermoplastic or thermosetting plastic, a conductive filler material such as chopped metal fibres, metal granules or metal powder, and a low melting-point metal alloy, such as a solder with a melting point of under 400° C., preferably 200° C. or less. Such materials are discussed in EP1695358, U.S. Pat. No. 6,274,070, JP2213002, EP0942436, U.S. Pat. No. 4,882,227, and U.S. Pat. No. 4,533,685. These materials are typically used to make electromagnetic shielding, or to form electrically conductive tracks on or in articles moulded of conventional plastics. Such plastic-metal hybrid materials may be made by an injection moulding process. Furthermore, articles may be made of the plastic-metal hybrid material by an injection moulding process.

During the injection moulding process, in the case of a thermoplastic component, the material is heated to a temperature at which both the plastic and the alloy are molten, or at least softened. Injection moulding may then take place as is conventional. On cooling, the material forms an interconnected network of conductive filler material joined by the low melting point alloy, embedded within the plastic component.

In the case of a plastic-metal hybrid material comprising a thermosetting component, injection moulding is carried out using uncured resin. If a low melting point metal alloy is included, the plastic-metal hybrid material should be heated to a temperature at which the alloy is molten, or at least softened.

The network of conductive filler joined by low melting point alloy forms thermally and electrically conductive tracks through the material. The respective surface tensions of the low melting-point metal alloy and the plastic means that the alloy causes the network of electrically conductive tracks to form, rather than the alloy dispersing through the plastic in unconnected droplets. The present invention concerns a new application of these plastic-metal hybrid materials, in which both the electrical and thermal properties of the material provide significant advantages.

According to an aspect of the present invention, a thermal radiation shield 1 is formed of a plastic-metal hybrid material comprising a plastic component, a conductive filler material and a low melting-point metal alloy.

Preferably, the plastic component is a thermoplastic, although a thermosetting plastic may be used in some embodiments of the present invention.

Preferably, the thermal radiation shield of the present invention is formed by injection moulding. The process of injection moulding is rapid, and allows many thermal radiation shields to be produced from a single mould, removing the need for skilled labour in the construction of the thermal radiation shield. Another significant advantage of an injection moulding process is that complex shapes, such as access holes for suspension elements for suspending the cryogen vessel may be formed during the moulding process, and need not be added later. Mounting points for suspension elements for suspending the thermal radiation shield may also be formed during the injection moulding process, rather than being added to the shield by skilled craftsmen, as is conventional with sheet metal thermal radiation shields.

Where chopped metal fibres are used as the conductive filler, it is found that injection moulding becomes more difficult with larger fibres. In the context of the present invention, it is preferred that chopped metal fibres have an average length of 25 mm or less, and more preferred that the chopped metal fibres should have an average length of 10 mm or less.

An example of a suitable plastic-metal hybrid material is shown in greater detail in FIG. 3, which is an enlarged cross section of a part of a thermal radiation shield according to the present invention. FIG. 3 shows the material of thermal radiation shield 1 as formed by an injection moulding technique in which a large number of electrically- and thermally-conductive tracks are embedded within insulating plastics material 23. As can be seen, a conductive filler material 21, in this example in the form of chopped metal fibres, is coated with low melting-point metal alloy 22. The separate metal fibres are mechanically, electrically and thermally joined by the low melting-point metal alloy, which acts a solder. Two of the chopped metal fibres are shown in cross-section, to illustrate how the low melting-point metal alloy coats and joins the chopped metal fibres. The joined chopped metal fibres are embedded within plastic 23.

In alternative embodiments, the conductive filler material comprises metal powder or metal granules. In such embodiments, a similar structure will develop, with electrically- and thermally-conductive tracks composed of conductive filler particles joined by low melting-point metal alloy embedded within an insulating plastic material.

Use of the insulating plastics material 23 reduces the amount of electrically conductive material used in the thermal radiation shield, which helps to reduce the eddy currents in the thermal radiation shield. The chopped fibres, granules or particles, of the conductive filler material are largely insulated from one another, providing relatively low volume regions of conductor, in which significant eddy currents will not develop.

In an example material, the conductive filler material comprises chopped copper fibres, of diameter less than 0.1 mm, and length 1 mm-10 mm. The low melting-point metal alloy may be a lead-tin (Pb—Sn) alloy, and the plastic may be a polyamide, or ABS (acrylonitrile butadiene styrene copolymer). The finished thermal radiation shield may have a thickness of 1-3 mm.

In certain embodiments of the invention, a low-emissivity coating 24 is applied to the outer surface of the thermal radiation shield. The low-emissivity coating provides a reflective surface to the thermal radiation shield to reduce heat absorption from the external environment, typically the outer vacuum container OVC 12. The low-emissivity coating may be a layer of aluminium, and may be sprayed on or applied as an adhesive tape or applied in other ways. Alternatively, or in addition, a similar low-emissivity coating may be applied to the inner surface of the thermal radiation shield. This low emissivity coating reduces thermal radiation from the shield towards the cryogen vessel 7.

In certain embodiments, the end faces 3 of the thermal radiation shield may not be formed from plastic-metal hybrid material. For example, they may be formed from sheets of high grade aluminium, as in conventional thermal radiation shields. In alternative embodiments, they may be formed of fibreglass reinforced thermosetting resin containing thermally conductive tracks, such as copper wire, interspaced therein. The thermally conductive tracks may be formed to provide conduction paths which flow generally upwards about the annulus as shown by the flow arrows depicted on the end face 3 in FIG. 2.

It is preferred, however, that the whole thermal radiation shield should be formed by injection moulding of a plastic-metal hybrid material. For example, two half-shields may be formed, each comprising one end face 3 and one axial half of each of the inner 4 and outer 5 cylinders. The two halves may be brought into position and joined together. In embodiments using a thermoplastic component, the edges of the cylindrical parts may be heated until the thermoplastic material and/or the low melting point metal alloy softens, and then pressing the two halves together. Embodiments including a thermosetting plastic component may be joined together using a compatible thermosetting adhesive. Of course, other arrangements may be made, for example the thermal radiation shield may be divided along a plane passing through the axis of the cylinders 4, 5. The thermal radiation shield may be formed by alternative moulding techniques such as rotary moulding or blow moulding. In some embodiments, the thermal radiation shield may be formed as a single piece, cut into two or more sections and then joined back together in position around the magnet 10 and any cryogen vessel 7.

To assist efficient cooling at the cooling area 2, a thermal intercept 8 may be provided, thermally linked to a refrigerator 17, for example by copper laminates or copper braid. According to an embodiment of the present invention, a thermal intercept, in the form of a solid component, or a copper laminate, or a copper braid, for example, may be connected to the thermal radiation shield 1 in a new manner. In embodiments of the invention which comprise a thermoplastic component, the material of the thermal radiation shield may be softened by local heating using a suitable tool and the thermal intercept may be pressed into the material of the thermal radiation shield. Depending on the application, a suitable tool may be a hot air gun, a soldering iron or a blowtorch. The thermal intercept will become thermally connected to the conductive tracks within the material of the thermal radiation shield, particularly if the material of the thermal radiation shield includes a low melting point alloy and the material of the thermal intercept is selected to be easily wetted by the low melting-point metal alloy. Tinned copper would be suitable material in embodiments using a lead-tin alloy as the low meting point metal alloy.

With the thermal radiation shield of the present invention, it is simple to attach ancillary components such as cables, connectors and thermal intercepts. With conventional thermal radiation shield, formed of sheet aluminium or the like, it was necessary to attach mounting features to the thermal radiation shield, then attach cables, connectors and so on to the mounting features.

With thermal radiation shields of the present invention which include a thermoplastic component, all that is required is to heat the relevant part of the thermal radiation shield using a suitable tool until the material of the thermal radiation shield becomes softened. Then, the cables, connectors and so on may be simply pressed into the material of the thermal radiation shield. As the material of the thermal radiation shield cools, the ancillary components become firmly retained in position by the material of the thermal radiation shield. Depending on the application, a suitable tool may be a hot air gun, a soldering iron or a blowtorch.

With thermal radiation shields of the present invention which include a thermosetting plastic component, all that is required is to attach the cables, connectors and so on using a compatible thermosetting adhesive.

For the thermal radiation shield of the present invention to operate effectively, the material of the thermal radiation shield needs to have a relatively high thermal conductivity. The inventors have found, however, that this thermal conductivity need not be as high as it is for aluminium, a material conventionally used for thermal radiation shields. On the other hand, in order to reduce eddy currents formed in the material of the thermal radiation shield, the electrical conductivity should be relatively low, preferably significantly lower than the electrical conductivity of aluminium, a material conventionally used for thermal radiation shields. In the plastic-metal hybrid material discussed above with reference to FIG. 3, conductive filler material is joined by low melting point metal alloy to form electrically and thermally conductive paths through the plastic. In certain embodiments of the present invention, it may be found beneficial to reduce the interconnection of conductive filler material, for example by reducing the proportion of the low melting point metal alloy in the material. This will have the effect of providing fewer interconnections between pieces of conductive filler.

Instead of being intricately linked by the low melting point metal alloy, parts of the conductive filler will not be connected. This will significantly increase the electrical resistivity of the material. However, the thermal conductivity of the material remains relatively high. The thermal conductivity may be improved by increasing the proportion of conductive filler.

In extreme embodiments, the low melting point metal alloy may be omitted entirely, and the thermal radiation shield may be formed of a material composed of a plastic containing conductive filler, typically in the form of chopped metal fibres or metal powder. The filler may comprise metal granules, or alternatives such as organic fibres coated with a metal. In such a material, most chopped fibres or particles or granules of filler are likely to be electrically isolated from all other chopped fibres, granules or particles by a layer of thermoplastic. This will provide a high level of electrical resistivity. However, since each chopped fibre or particle is likely to be separated from its neighbours by only a thin layer of plastic, the thermal conductivity of the material may still be acceptably high. The thermal conductivity of the material may be controlled by varying the material used as the conductive filler, for example, copper, aluminium, steel, and the size of the granules or particles used, or the diameter and length of the chopped fibres used. The thermal conductivity may also be controlled by varying the proportion of the conductive filler within the material.

As the conductive particles, granules or chopped fibres do not form long electrically conductive paths in such embodiments, the tendency for eddy currents to develop within the material of the thermal radiation shield will be significantly reduced.

Further advantages of the thermal radiation shield of the present invention include the reduction in the mass of the thermal radiation shield, which may lead to economies in transport and easier handling during manufacture.

The manufacture of the thermal radiation shields of the invention may be entrusted to an organisation specialising in plastics moulding. This will remove responsibility for thermal radiation shield manufacture from the manufacturer of the magnets or cryostats. The thermal radiation shield may be expected to be highly repeatable in terms of dimensions, and assembly of the thermal radiation shield into a cryostat may be much simpler than is the case with conventional thermal radiation shields.

While the present invention has been described with reference to certain embodiments, numerous modifications and variations will be apparent to those skilled in the art, within the scope of the present invention. For example, the plastic-metal hybrid may include a mixture of at least two types of conductive filler, selected from chopped fibre, powder and granules. The conductive filler may be of more than one type of metal. Non-conductive filler materials such as glass fibres or talc may also be included, to provide desired mechanical properties.

1. A thermal radiation shield for a cryostat, formed of a plastic-metal hybrid material comprising a plastic component and a conductive filler material comprising a metal.

2. A thermal radiation shield according to claim 1 wherein the conductive filler component of the plastic-metal hybrid material comprises chopped metal fibres.

3. A thermal radiation shield according to claim 2 wherein the chopped metal fibres have an average length of 25 mm or less.

4. A thermal radiation shield according to claim 3 wherein the chopped metal fibres have an average length of 10 mm or less.

5. A thermal radiation shield according to claim 1 wherein the conductive filler component of the plastic-metal hybrid material metal powder.

6. A thermal radiation shield according to claim 1 wherein the conductive filler component of the plastic-metal hybrid material metal granules.

7. A thermal radiation shield according to claim 1 wherein the plastic component of the plastic-metal hybrid material comprises a thermoplastic material.

8. A thermal radiation shield according to claim 1 wherein the plastic-metal hybrid material further comprises a low melting-point metal alloy.

9. A thermal radiation shield according to claim 8 wherein the low melting-point metal alloy has a melting point of less than 400° C.

10. A thermal radiation shield according to claim 9 wherein the low melting-point metal alloy has a melting point of 200° C. or less.

11. A thermal radiation shield as claimed in claim 1 having a low emissivity layer applied over an inner and/or outer surface.

12. A thermal radiation shield according to claim 1, formed by injection moulding of the plastic-metal hybrid material.

13. A thermal radiation shield according to claim 1, wherein the plastic-metal hybrid includes a mixture of at least two types of conductive filler, selected from chopped fibre, powder and granules.

14. A thermal radiation shield according to claim 1, wherein the plastic-metal hybrid includes a non-conductive filler material.

15. A thermal radiation shield according to claim 1, comprising an inner cylinder of plastic-metal hybrid material and an outer cylinder of plastic-metal hybrid material, joined by annular end faces 3 not of plastic-metal hybrid material.

16. A thermal radiation shield according to claim 15 wherein at least one of the annular end faces is formed of insulating material containing thermally conductive tracks.

17. A cryostat for housing a superconducting magnet comprising a thermal radiation shield according to claim 1 located within a vacuum region of an outer vacuum container.

18. A cryostat housing a superconducting magnet comprising a thermal radiation shield according to claim 1 surrounding the superconducting magnet and located within a vacuum region of an outer vacuum container.

19. A cryostat housing a superconducting magnet according to claim 18, wherein the superconducting magnet is located within a cryogen vessel which is surrounded by the thermal radiation shield.

20. An MRI system comprising a cryostat housing a superconducting magnet according to claim 18.
